(19) United States
(12) Patent Application Publication
(10) Pub. No.: US 2025/0374801 A1
(43) Pub. Date: Dec. 4, 2025

(54) LIGHT EMITTING DEVICE, ELECTRONIC APPARATUS, AND SEALING DEVICE

(71) Applicant: Sony Semiconductor Solutions Corporation, Kanagawa (JP)

(72) Inventors: Tsutomu Shimayama, Kanagawa (JP); Keiichi Yagi, Kanagawa (JP)

(21) Appl. No.: 18/869,173

(22) PCT Filed: Jul. 5, 2023
(86) PCT No.: PCT/JP2023/024950

§ 371 Date: Nov. 25, 2024

(30) Foreign Application Priority Data
Jul. 12, 2022 (JP) 2022-112064

(51) Int. Cl. H10K 59/80

(52) U.S. Cl. CPC H10K 59/873

(57) ABSTRACT

Light emitting devices with moisture entry prevention are disclosed. In one example, a light emitting device includes light emitting elements provided in a display region, a Si-containing layer covering the light emitting elements, a metal oxide layer provided on the Si-containing layer, and a seal portion that is provided outside the display region and contains an organic resin. The Si-containing layer has an exposed portion that is exposed outside the display region without being covered with the metal oxide layer, and the seal portion is in contact with the exposed portion.

### TECHNICAL FIELD The present disclosure relates to a light emitting device, and an electronic apparatus and a sealing device each including the light emitting device.

### BACKGROUND ART

Light emitting devices in which a plurality of organic light emitting diode (OLED) elements is two-dimensionally arranged are widely used. In the light emitting device, various sealing structures have been studied to prevent entry of moisture from the outside. For example, Patent Document 1 discloses an organic electronic device sealing film that includes: a metal layer; and a sealing layer that is provided on a first surface of the metal layer and is positioned on the inner side of an end portion of the first surface so that the end portion of a partial region forms a gap with the end portion of the first surface, and the sealing layer includes a pressure-sensitive adhesive layer and an adhesive layer.

### CITATION LIST

### Patent Document

Patent Document 1: Japanese Patent Application Laid-Open No. 2020-143295

### SUMMARY OF THE INVENTION

### Problems to be Solved by the Invention

With the conventional sealing structure, however, entry of moisture might not be adequately prevented, and there is room for improvement.

The present disclosure aims to provide a light emitting device capable of preventing entry of moisture, and an electronic apparatus and a sealing device each including the light emitting device.

### Solutions to Problems

To solve the above problems, a first light emitting device according to the present disclosure includes:
a plurality of light emitting elements provided in a display region;
a Si-containing layer that covers the plurality of light emitting elements;
a metal oxide layer provided on the Si-containing layer; and
a seal portion that is provided outside the display region and contains an organic resin, in which
the Si-containing layer has an exposed portion that is not covered with the metal oxide layer and is exposed outside the display region, and
the seal portion is in contact with the exposed portion.

A second light emitting device according to the present disclosure includes:
a plurality of light emitting elements provided in a display region;
a first Si-containing layer that covers the plurality of light emitting elements; a metal oxide layer provided on the first Si-containing layer;
a second Si-containing layer provided on the metal oxide layer; and
a seal portion that is provided outside the display region and contains an organic resin, in which
the seal portion is in contact with the second Si-containing layer outside the display region.

A first sealing device according to the present disclosure includes:
a plurality of elements provided in an element formation region;
a Si-containing layer that covers the plurality of elements;
a metal oxide layer provided on the Si-containing layer; and
a seal portion that is provided outside the element formation region and contains an organic resin, in which
the Si-containing layer has an exposed portion that is not covered with the metal oxide layer and is exposed outside the element formation region, and
the seal portion is in contact with the exposed portion.

A second sealing device according to the present disclosure includes:
a plurality of elements provided in an element formation region;
a first Si-containing layer that covers the plurality of elements;
a metal oxide layer provided on the first Si-containing layer;
a second Si-containing layer provided on the metal oxide layer; and
a seal portion that is provided outside the element formation region and contains an organic resin, in which
the seal portion is in contact with the second Si-containing layer outside the element formation region.

A first electronic apparatus according to the present disclosure includes the first light emitting device or the second light emitting device.

A second electronic apparatus according to the present disclosure includes the first sealing device or the second sealing device.

### BRIEF DESCRIPTION OF DRAWINGS

FIG. 1 is a cross-sectional view for explaining an outline of the present disclosure.

FIG. 2 is a plan view illustrating an example of an external appearance of a display device according to a first embodiment.

FIG. 3 is a cross-sectional view taken along the line III-III defined in FIG. 2.

FIG. 4A is a plan view illustrating an example of a Si-containing layer and a metal oxide layer. FIG. 4B is a cross-sectional view taken along the line IVB-IVB defined in FIG. 4A.

FIGS. 5A and 5B are views, each of which is for explaining a mechanism for increasing adhesiveness.

FIGS. 6A and 6B are views, each of which is for explaining a mechanism for increasing adhesiveness.

FIG. 7 is a cross-sectional view illustrating an example configuration of a display device according to Modification 1.

FIG. 8A is a plan view illustrating an example of a Si-containing layer and a metal oxide layer provided in a display device according to Modification 2. FIG. 8B is a cross-sectional view taken along the line VIIIB-VIIIB defined in FIG. 8A.

FIG. 9A is a plan view illustrating an example of a Si-containing layer and a metal oxide layer provided in a display device according to Modification 3. FIG. 9B is a cross-sectional view taken along the line IXB-IXB defined in FIG. 9A.

FIG. 10A is a plan view illustrating an example of a Si-containing layer and a metal oxide layer provided in a display device according to Modification 4. FIG. 10B is a cross-sectional view taken along the line XB-XB defined in FIG. 10A.

FIG. 11A is a plan view illustrating an example of a Si-containing layer and a metal oxide layer provided in a display device according to Modification 5. FIG. 11B is a cross-sectional view taken along the line XIB-XIB defined in FIG. 11A.

FIG. 12 is a cross-sectional view illustrating an example configuration of a display device according to a second embodiment.

FIG. 13A is a plan view illustrating an example of a Si-containing layer and a metal oxide layer provided in a display device according to Modification 1. FIG. 13B is a cross-sectional view taken along the line XIIIB-XIIIB defined in FIG. 13A.

FIG. 14A is a plan view illustrating an example of a Si-containing layer and a metal oxide layer provided in a display device according to Modification 2. FIG. 14B is a cross-sectional view taken along the line XIVB-XIVB defined in FIG. 14A.

FIG. 15A is a front view illustrating an example of an external appearance of a digital still camera. FIG. 15B is a rear view illustrating an example of an external appearance of the digital still camera.

FIG. 16 is a perspective view illustrating an example of an external appearance of a head-mounted display.

FIG. 17 is a perspective view illustrating an example of an external appearance of a television apparatus.

FIG. 18 is a perspective view illustrating an example of an external appearance of a see-through head-mounted display.

FIG. 19 is a perspective view illustrating an example of an external appearance of a smartphone.

FIG. 20A is a view illustrating an example of an internal state of a vehicle as viewed from the rear to the front of the vehicle. FIG. 20B is a diagram illustrating an example of an internal state of the vehicle as viewed from an oblique rear to an oblique front of the vehicle.

### MODE FOR CARRYING OUT THE INVENTION

Embodiments of the present disclosure will be described in the following order, with reference to the drawings. Note that the same or corresponding portions will be denoted by the same reference signs in all the drawings of the embodiments described below.
1. Overview
2. First embodiment (an example of a display device)
3. Second embodiment (an example of a display device)
4. Modifications
5. Example applications (examples of electronic apparatuses)

### 1. Overview

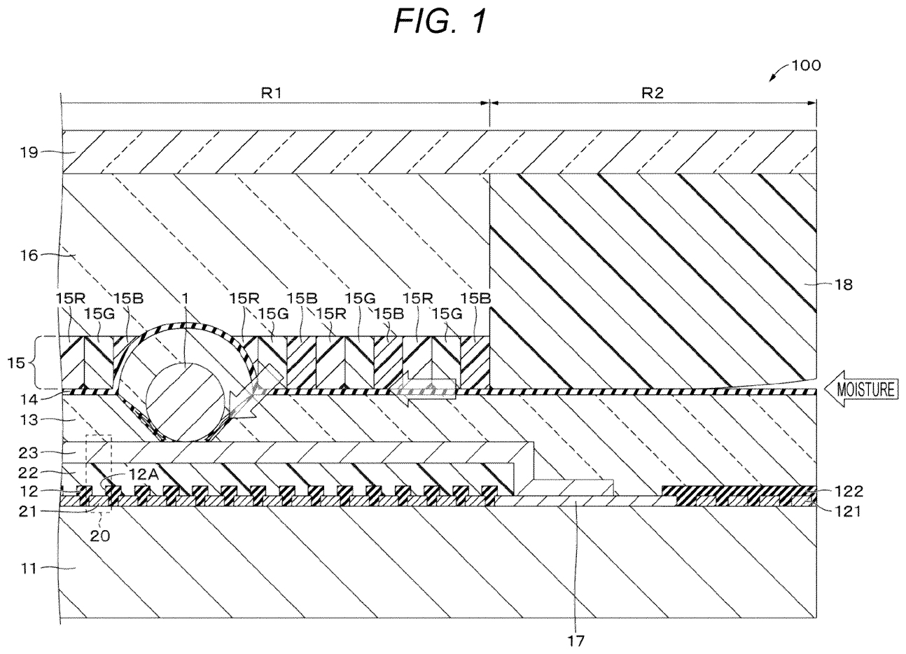

As illustrated in FIG. 1, when a seal portion 18 is provided on a metal oxide layer 14, the adhesiveness of the seal portion 18 to the metal oxide layer 14 is low, and therefore, moisture easily enters the inside of a display device 100 from the outside. Entry of moisture into the display device 100 causes a decrease in reliability of the display device 100. In particular, moisture intrusion that occurs in the process as described below might turn into a major cause of a decrease in reliability of the display device 100.
(1) A particle 1 adheres thereto during the process of manufacturing the display device 100 (in particular, during the formation of an organic layer or a metal layer).
(2) The coverage (covering properties) of a protective layer (a Si-containing layer 13 and the metal oxide layer 14) formed thereafter is degraded due to the particle, and a leak path is formed.
(3) Moisture enters the inside of the display device 100 via the leak path starting from peeling or the like of the seal portion 18, and adversely affects the reliability of the display device 100. The arrows in FIG. 1 indicate the entry path of moisture into the display device 100.

The present inventors have extensively conducted studies for increasing the adhesiveness between the seal portion 18 and the underlayer, on the basis of the mechanism of the above decrease in reliability. As a result, the present inventors have found that it is possible to increase the adhesiveness between the seal portion 18 and the underlayer by removing all or part of the portion of the metal oxide layer 14 located below the seal portion 18, and bringing the Si-containing layer 13 and the metal oxide layer 14 into direct contact with each other.

### 2. First Embodiment

### [Configuration of a Display Device 10]

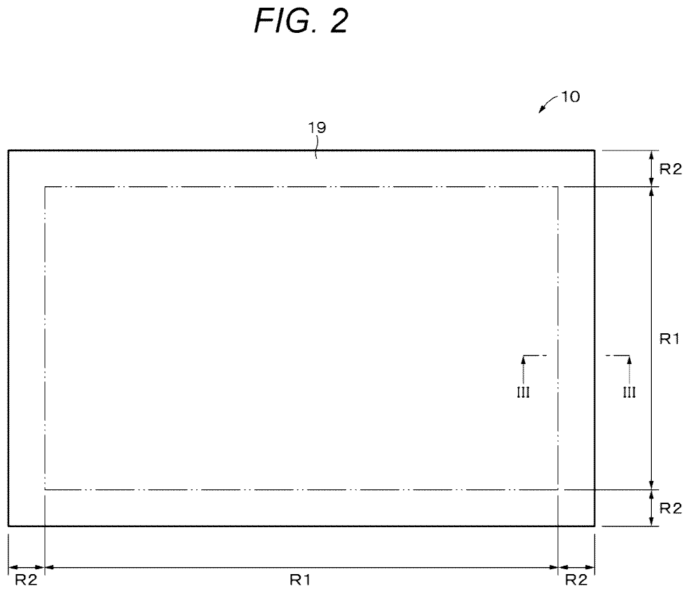

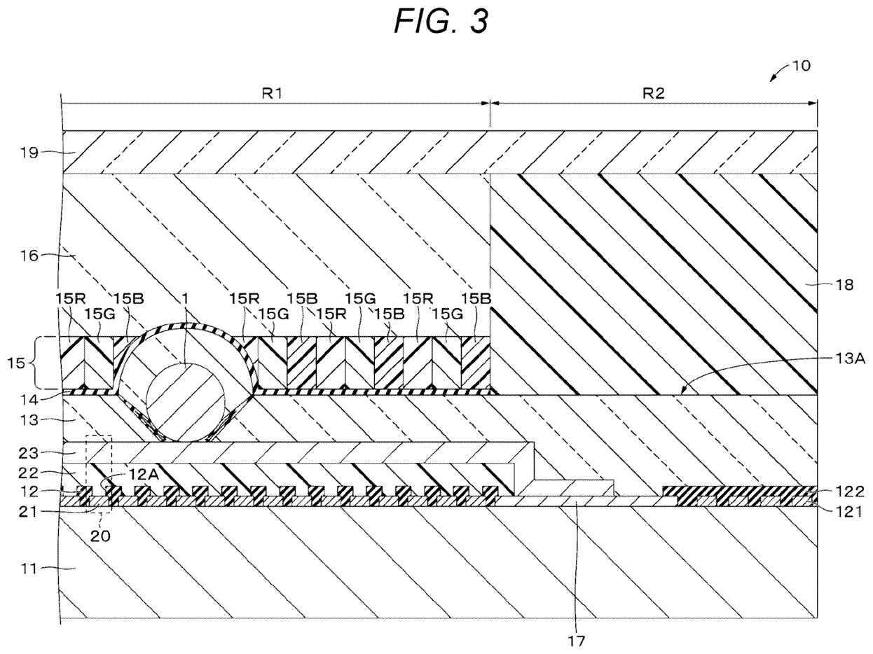

FIG. 2 is a plan view illustrating an example of an external appearance of a display device 10 according to the first embodiment. FIG. 3 is a cross-sectional view taken along the line III-III defined in FIG. 2. The display device 10 includes a display region R1 and a seal region R2. The display region R1 is an element formation region in which a plurality of light emitting elements 20 is formed. The display region R1 has a quadrangular shape in a planar view, for example. Examples of quadrangular shapes include rectangular shapes and parallelogram shapes, but other quadrangular shapes may be used. In the present specification, rectangular shapes also include square shapes. Note that the shape of the display region R1 is not necessarily a quadrangular shape, and can be any appropriately selected shape. For example, the shape may be a polygonal shape other than quadrangular shapes, a circular shape, an elliptical shape, or the like. The seal region R2 is a region in which the seal portion 18 is provided. The seal region R2 is located outside the display region R1. The seal region R2 is in the form of a closed loop surrounding the display region R1 in a planar view. Although FIG. 2 illustrates an example in which the seal region R2 is adjacent to the display region R1, a space may be kept between the seal region R2 and the display region R1, and both regions may be separated from each other.

The display device 10 is an example of a light emitting device. The display device 10 is a top-emitting OLED display device. The display device 10 may be a microdisplay. The display device 10 may be provided in a virtual reality (VR) device, a mixed reality (MR) device, an augmented reality (AR) device, an electronic viewfinder (EVF), a small projector, or the like.

The display device 10 includes a circuit board 11, a plurality of light emitting elements 20, an insulating layer 12, a Si-containing layer 13, a metal oxide layer 14, a color filter 15, a filling resin layer 16, a contact portion 17, a seal portion 18, and a counter substrate 19.

The display device 10 may further include a pad portion (not illustrated). A flexible printed circuit (FPC) may be connected to the pad portion. Note that, in a case where the display device 10 includes a pad portion, the seal region R2 may be provided on the inner side of the pad portion.

The display device 10 may include a plurality of dummy electrodes 121 and an insulating layer 122. The dummy electrodes 121 are provided on a first surface of the circuit board 11 in the seal region R2. The insulating layer 122 covers the plurality of dummy electrodes 121.

In the present specification, in each of the layers constituting the display device 10, a surface on the top side (display surface side) of the display device 10 is referred to as a first surface, and a surface on the bottom side (a side opposite to the display surface) of the display device 10 is referred to as a second surface. Also, in the present specification, a planar view means a planar view when an object is viewed from a direction perpendicular to the first surface.

### (Circuit Board 11)

The circuit board 11 is a so-called backplane, and drives the plurality of light emitting elements 20. The circuit board 11 includes a substrate. A plurality of wiring lines, a drive circuit that drives the plurality of light emitting elements 20, a power supply circuit that supplies power to the plurality of light emitting elements 20, and the like (any of which is not illustrated) are provided on the first surface of the substrate. An insulating layer covers the first surface of the substrate, and planarizes the first surface of the substrate.

The substrate may be formed with a semiconductor that is easy to form, such as a transistor, or may be formed with glass or resin having low moisture and oxygen permeability, for example. Specifically, the substrate may be a semiconductor substrate, a glass substrate, a resin substrate, or the like. The semiconductor substrate contains amorphous silicon, polycrystalline silicon, monocrystalline silicon, or the like, for example. The glass substrate contains high-strain-point glass, soda glass, borosilicate glass, forsterite, lead glass, quartz glass, or the like, for example. The resin substrate contains at least one kind selected from the group consisting of polymethyl methacrylate, polyvinyl alcohol, polyvinyl phenol, polyethersulfone, polyimide, polycarbonate, polyethylene terephthalate, polyethylene naphthalate, and the like, for example.

### (Light Emitting Elements 20)

The light emitting elements 20 are white OLED element, and can emit white light under the control of the drive circuit or the like. The white OLED elements may be white micro-OLED (MOLED) elements. The plurality of light emitting elements 20 is two-dimensionally arranged on the first surface of the circuit board 11 in a prescribed layout pattern. The light emitting elements 20 each include a first electrode 21, an OLED layer 22, and a second electrode 23 in this order on the first surface of the circuit board 11.

### (First Electrode 21)

The first electrode 21 is an anode. When a voltage is applied between the first electrode 21 and the second electrode 23, holes are injected from the first electrode 21 into the OLED layer 22. The first electrode 21 has a planar shape perpendicular to the thickness direction of the light emitting element 20. The first electrodes 21 are divided between the adjacent light emitting elements 20, and are separately provided for the plurality of light emitting elements 20. The plurality of first electrodes 21 is two-dimensionally arranged on the first surface of the circuit board 11 in a layout pattern similar to that of the plurality of light emitting elements 20.

The first electrode 21 may be formed with a metal layer also serving as a reflective layer, or may be formed with a metal layer and a transparent conductive oxide layer, for example. In a case where the first electrode 21 is formed with a metal layer and a transparent conductive oxide layer, the transparent conductive oxide layer is preferably provided on the side of the OLED layer 22 to place a high-work-function layer at a location adjacent to the OLED layer 22.

The metal layer also has functions as a reflective layer that reflects light emitted from the OLED layer 22. The metal layer contains at least one metal selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may contain the at least one metal mentioned above as a constituent element of an alloy. Specific examples of the alloy include an aluminum alloy and a silver alloy. Specific examples of the aluminum alloy include AlNd and AlCu, for example.

An underlayer (not shown) may be provided adjacent to the second surface side of the metal layer. The underlayer can improve the crystalline orientation of the metal layer at the time of formation of the metal layer. The underlayer contains at least one metal selected from the group consisting of titanium (Ti) and tantalum (Ta), for example. The underlayer may contain the at least one metal mentioned above as a constituent material of the alloy.

The transparent conductive oxide layer contains a transparent conductive oxide. The transparent conductive oxide contains at least one kind selected from the group consisting of indium-containing transparent conductive oxides (hereinafter referred to as “indium-based transparent conductive oxides”), tin-containing transparent conductive oxides (hereinafter referred to as “tin-based transparent conductive oxides”), and zinc-containing transparent conductive oxides (hereinafter referred to as “zinc-based transparent conductive oxides”), for example.

The indium-based transparent conductive oxides include indium tin oxide (ITO), indium zinc oxide (IZO), indium gallium oxide (IGO), indium gallium zinc oxide (IGZO), and fluorine-doped indium oxide (IFO), for example. Among these transparent conductive oxides, indium tin oxide (ITO) is particularly preferable. This is because indium tin oxide (ITO) has a particularly low barrier for hole injection into the OLED layer 22 in terms of work function, and accordingly, the drive voltage for the display device 10 can be particularly reduced. The tin-based transparent conductive oxides include tin oxide, antimony-doped tin oxide (ATO), and fluorine-doped tin oxide (FTO), for example. The zinc-based transparent conductive oxides include zinc oxide, aluminum-doped zinc oxide (AZO), boron-doped zinc oxide, and gallium-doped zinc oxide (GZO), for example.

### (OLED Layer 22)

The OLED layer 22 is an example of an organic layer including a light emitting layer. The OLED layer 22 can emit white light by recombination of holes injected from the first electrodes 21 and electrons injected from the second electrode 23.

The OLED layer 22 is provided over the plurality of first electrodes 21. The OLED layer 22 is connected between the adjacent light emitting elements 20 in the display region R1, and is shared by the plurality of light emitting elements 20 in the display region R1.

The OLED layer 22 may be an OLED layer including a single-layer light emitting unit, an OLED layer including a two-layer light emitting unit (a tandem structure), or an OLED layer having a structure other than these structures. The OLED layer including a single-layer light emitting unit has a configuration in which a hole injection layer, a hole transport layer, a red light emitting layer, a light emitting separation layer, a blue light emitting layer, a green light emitting layer, an electron transport layer, and an electron injection layer are stacked in this order in the direction from the first electrodes 21 toward the second electrode 23, for example. The OLED layer including a two-layer light emitting unit has a configuration in which a hole injection layer, a hole transport layer, a blue light emitting layer, an electron transport layer, a charge generation layer, a hole transport layer, a yellow light emitting layer, an electron transport layer, and an electron injection layer are stacked in this order in the direction from the first electrodes 21 toward the second electrode 23, for example.

The hole injection layer can enhance the efficiency of hole injection into each light emitting layer, and suppress leakage. The hole transport layer can enhance the efficiency of hole transport to each light emitting layer. The electron injection layer can enhance the efficiency of electron injection into each light emitting layer. The electron transport layer can enhance the efficiency of electron transport to each light emitting layer. The light emitting separation layer is a layer that can adjust injection of carriers into each light emitting layer, and light emission balance of each color is adjusted by injection of electrons or holes into each light emitting layer via the light emitting separation layer. The charge generation layer can individually supply electrons and holes to two light emitting layers sandwiching the charge generation layer.

In response to application of an electric field to each of the red light emitting layer, the green light emitting layer, the blue light emitting layer, and the yellow light emitting layer, recombination occurs between holes injected from the first electrodes 21 or the charge generation layer and electrons injected from the second electrode 23 or the charge generation layer, and red light, green light, blue light, and yellow light can be emitted.

### (Second Electrode 23)

The second electrode 23 is a cathode. When a voltage is applied between the first electrode 21 and the second electrode 23, electrons are injected from the second electrode 23 into the OLED layer 22. The second electrode 23 is a transparent electrode having transparency to visible light. In the present specification, visible light refers to light in a wavelength region of 360 nm to 830 nm. The second electrode 23 is provided on the first surface of the OLED layer 22. The second electrode 23 is connected between the adjacent light emitting elements 20 in the display region R1, and is shared by the plurality of light emitting elements 20 in the display region R1.

The second electrode 23 is preferably formed with a material having as high a transparency as possible and a small work function, to enhance luminous efficiency. The second electrode 23 is formed with at least one of a metal layer or a transparent conductive oxide layer, for example. More specifically, the second electrode 23 is formed with a single-layer film of a metal layer or a transparent conductive oxide layer, or a film stack of a metal layer and a transparent conductive oxide layer. In a case where the second electrode 23 is formed with a film stack, the metal layer may be provided on the side of the OLED layer 22, or the transparent conductive oxide layer may be provided on the side of the OLED layer 22. However, to place a low-work-function layer at a position adjacent to the OLED layer 22, the metal layer is preferably provided on the side of the OLED layer 22.

The metal layer contains at least one metal selected from the group consisting of magnesium (Mg), aluminum (Al), silver (Ag), calcium (Ca), and sodium (Na), for example. The metal layer may contain the at least one metal mentioned above as a constituent element of an alloy. Specific examples of the alloy includes an MgAg alloy, an MgAl alloy, an AlLi alloy, and the like. The transparent conductive oxide layer contains a transparent conductive oxide. As the transparent conductive oxide, a material similar to the transparent conductive oxide of the first electrode 21 described above can be taken as an example.

### (Insulating Layer 12)

The insulating layer 12 insulates the adjacent first electrodes 21 from each other. The insulating layer 12 is provided in a portion between the separated first electrodes 21 on the first surface of the circuit board 11. The insulating layer 12 has a plurality of openings 12A. Each opening of the plurality of openings 12A is provided for each corresponding light emitting element 20. More specifically, each opening of the plurality of openings 12A is provided on the first surface (the surface on the side of the OLED layer 22) of each corresponding first electrode 21. The first electrodes 21 and the OLED layer 22 are in contact with each other via the openings 12A.

The insulating layer 12 may be an organic insulating layer, an inorganic insulating layer, or a stack member formed with these layers. The organic insulating layer contains at least one resin selected from the group consisting of polyimide-based resin, acrylic resin, novolac-based resin, and the like, for example. The inorganic insulating layer contains at least one silicon selected from the group consisting of silicon oxide (SiOₓ), silicon nitride (SiNₓ), silicon oxynitride (SiOₓN_{y}), and the like, for example.

### (Si-Containing Layer 13, and Metal Oxide Layer 14)

The Si-containing layer 13 is a first protective layer that protects the plurality of light emitting elements 20. The Si-containing layer 13 has transparency to visible light. The Si-containing layer 13 is provided on the first surface of the second electrode 23, and covers the plurality of light emitting elements 20. The Si-containing layer 13 can prevent entry of moisture into the plurality of light emitting elements 20 from an external environment.

The Si-containing layer 13 contains silicon (Si) and nitrogen (N), or contains silicon (Si), oxygen (O), and nitrogen (N), for example. Specifically, the Si-containing layer 13 contains silicon nitride (SiNₓ) or silicon oxynitride (SiOₓN_{y}), for example. The Si-containing layer 13 may contain silicon (Si) and oxygen (O) in the surface (interface) joined to the seal portion 18. In this case, oxygen (O) may not be a principal component of the Si-containing layer 13.

The metal oxide layer 14 is a second protective layer that protects the plurality of light emitting elements 20. The metal oxide layer 14 has transparency to visible light. The metal oxide layer 14 is provided on the Si-containing layer 13, and covers the plurality of light emitting elements 20. The Si-containing layer 13 can prevent entry of moisture into the plurality of light emitting elements 20 from an external environment.

The metal oxide layer 14 is preferably formed with a deposit of a monolayer. When the metal oxide layer 14 is formed with a deposit of a monolayer, the effect of the metal oxide layer 14 suppressing entry of moisture can be increased. The metal oxide layer 14 contains aluminum oxide (AlOₓ) or titanium oxide (TiOₓ), for example. The metal oxide layer 14 may be an ALD layer.

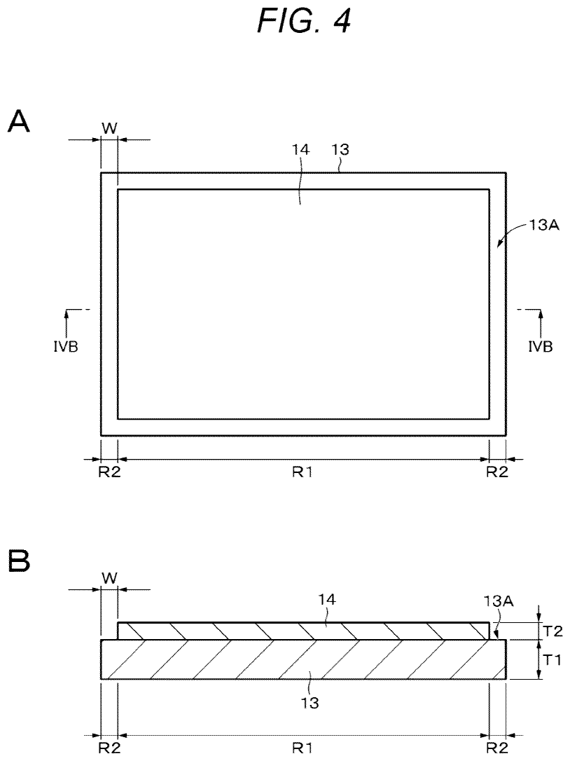

FIG. 4A is a plan view illustrating an example of the Si-containing layer 13 and the metal oxide layer 14. FIG. 4B is a cross-sectional view taken along the line IVB-IVB defined in FIG. 4A. The peripheral edge of the metal oxide layer 14 is recessed with respect to the peripheral edge of the Si-containing layer 13. Because of this, the peripheral edge portion of the first surface of the Si-containing layer 13 is exposed without being covered with the metal oxide layer 14, and an exposed portion 13A is formed. In the present specification, the peripheral edge portion of the first surface refers to a region having a predetermined width in the direction from the peripheral edge of the first surface toward the inside.

The exposed portion 13A is located in the seal region R2. The exposed portion 13A is preferably in the form of a closed loop surrounding the display region R1 in a planar view. The substantially entire seal region R2 may be the exposed portion 13A. That is, the width of the seal region R2 may be substantially the same as the width of the exposed portion 13A.

The thickness T1 of the Si-containing layer 13 is preferably 10 μm or smaller, or more preferably, 5 μm or smaller. Where the thickness T1 of the Si-containing layer 13 is 10 μm or smaller, an increase in the distance between the light emitting element 20 and the color filter 15 can be reduced, and thus, degradation in the viewing angle characteristics can be reduced.

The thickness T2 of the metal oxide layer 14 is preferably 200 nm or smaller. Where the thickness T2 of the metal oxide layer 14 is 200 nm or smaller, a decrease in productivity due to the film formation time of the metal oxide layer 14 can be reduced. The lower limit value of the thickness T2 of the metal oxide layer 14 is preferably 5 nm or greater. Where the thickness T2 of the metal oxide layer 14 is 5 nm or greater, degradation of the functions of the metal oxide layer 14 as a protective layer can be reduced.

The width W of the exposed portion 13A is preferably 5 mm or smaller, or more preferably, 2 mm or smaller, to make the frame of the display device 10 narrower.

### (Color Filter 15)

The color filter 15 is provided on the first surface of the metal oxide layer 14. The color filter 15 is an on-chip color filter (OCCF). The color filter 15 includes a plurality of red filter portions 15R, a plurality of green filter portions 15G, and a plurality of blue filter portions 15B.

The plurality of filter portions 15R, 15G, and 15B is two-dimensionally arranged on the first surface of the metal oxide layer 14 in a prescribed layout pattern similar to that of the plurality of light emitting elements 20. The respective filter portions 15R, 15G, and 15B are provided above the light emitting elements 20. The light emitting elements 20 and the red filter portions 15R provided above the light emitting elements 20 constitute red subpixels. The light emitting elements 20 and the green filter portions 15G provided above the light emitting elements 20 constitute green subpixels. The light emitting elements 20 and the blue filter portions 15B provided above the light emitting elements 20 constitute blue subpixels.

The red filter portions 15R transmit red light out of white light emitted from the light emitting elements 20, and absorb light other than the red light. The green filter portions 15G transmit green light out of the white light emitted from the light emitting elements 20, and absorb light other than the green light. The blue filter portions 15B transmit blue light out of the white light emitted from the light emitting elements 20, and absorb light other than the blue light.

The red filter portions 15R include a red color resist, for example. The green filter portions 15G include a green color resist, for example. The blue filter portions 15B include a blue color resist, for example.

### (Filling Resin Layer 16)

The filling resin layer 16 is provided between the color filter 15 and the counter substrate 19. The filling resin layer 16 may have functions as an adhesive layer for bonding the color filter 15 and the counter substrate 19. The filling resin layer 16 contains at least one resin selected from the group consisting of thermosetting resins, ultraviolet curable resins, and the like, for example.

### (Contact Portion 17)

The contact portion 17 is an auxiliary electrode that connects the second electrode 23 and an underlying wiring line or the like (not illustrated). The first surface of the contact portion 17 is connected to a peripheral edge portion of the second surface of the second electrode 23. Meanwhile, the second surface of the contact portion 17 is connected to the underlying wiring line or the like via a contact plug. In the present specification, the peripheral edge portion of the second surface refers to a region having a predetermined width in the direction from the peripheral edge of the second surface toward the inside.

The contact portion 17 is provided on the first surface of the circuit board 11 in the seal region R2. The contact portion 17 may have the shape of a closed loop surrounding the display region R1 in a planar view.

The contact portion 17 may be formed with a metal layer, or may be formed with a metal layer and a transparent conductive oxide layer. As the constituent materials of the metal layer and the transparent conductive oxide layer, materials similar to those of the metal layer and the transparent conductive oxide layer of the first electrodes 21 can be taken as an example. The contact portion 17 may have the same configuration as the first electrodes 21.

### (Seal Portion 18)

The seal portion 18 bonds the exposed portion 13A of the Si-containing layer 13 to the peripheral edge portion of the second surface of the counter substrate 19. The seal portion 18 is provided between the exposed portion 13A of the Si-containing layer 13 and the peripheral edge portion of the second surface of the counter substrate 19, and is in direct contact with the exposed portion 13A of the Si-containing layer 13 in the seal region R2. The seal portion 18 has the shape of a closed loop in a planar view.

The seal portion 18 contains an organic resin. The organic resin may contain carbon (C) and hydrogen (O) as principal components. The organic resin contains at least one resin selected from the group consisting of thermosetting resins, ultraviolet curable resins, and the like, for example. More specifically, the organic resin contains at least one resin selected from the group consisting of epoxy resins, acrylic resins, and the like, for example. Note that the organic resin is not limited to thermosetting resins and ultraviolet curable resins, and may contain some other kind of curable resin that is neither a thermosetting resin nor an ultraviolet curable resin.

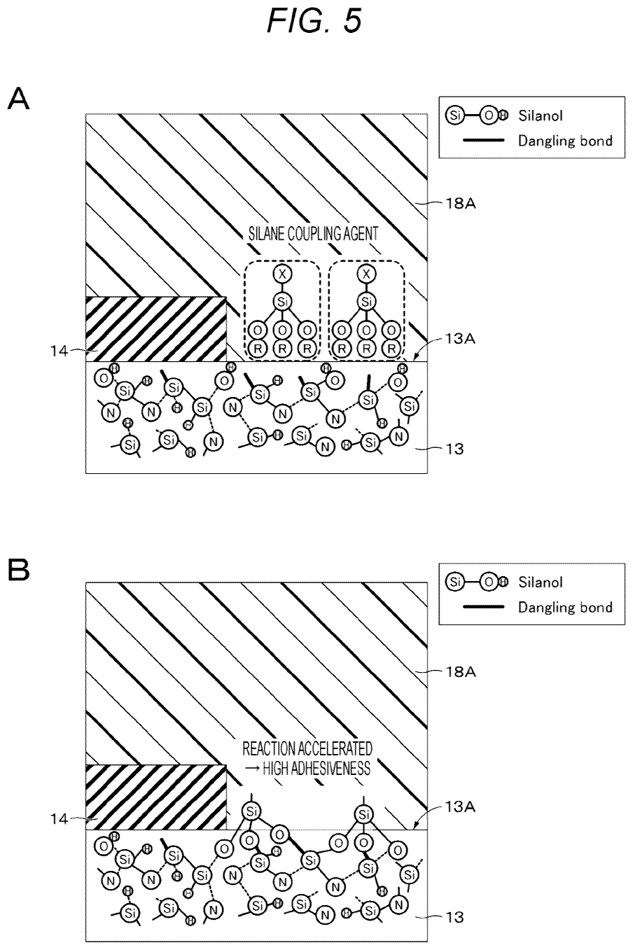

The joint interface between the Si-containing layer 13 and the seal portion 18 preferably contains Si—O bonds as illustrated in FIG. 5B. As the Si-containing layer 13 and the seal portion 18 are bonded to each other via the Si—O bonds, adhesiveness between the Si-containing layer 13 and the seal portion 18 can be increased.

The seal portion 18 preferably contains a silane coupling agent. As the seal portion 18 contains a silane coupling agent, Si—O bonds can be formed at the joint interface between the Si-containing layer 13 and the seal portion 18.

The silane coupling agent may contains the two of a reactive group site X and an alkoxyl group site OR in a molecule. The silane coupling agent may be an alkoxysilane compound expressed by the general formula X—Si(OR)₃, but it is possible to use any silane coupling agent that can be synthesized and contains a reactive group site X and an alkoxyl group site OR in a molecule.

The R of the silane coupling agent is an alkyl group or a derivative thereof. The alkyl group is a methyl group, an ethyl group, a butyl group, an isopropyl group, or the like, for example.

The reactive group site X of the silane coupling agent has a structure containing at least one reactive group selected from the group consisting of an amino group, a vinyl group, an epoxy group, a methacrylic group, a mercapto group, a sulfide group, an isocyanate group, a ureido group, a chloropropyl group, a hydroxyl group, and the like, for example.

### (Counter Substrate 19)

The counter substrate 19 seals each member provided on the first surface of the circuit board 11. The counter substrate 19 has transparency to visible light, for example. The counter substrate 19 is provided on both the first surface of the filling resin layer 16 and the first surface of the seal portion 18, and faces the circuit board 11. The counter substrate 19 is a glass substrate, for example.

### [Method for Manufacturing the Display Device 10]

In the description below, an example of a method of manufacturing the display device 10 according to the first embodiment is explained.

### (Step of Forming the First Electrodes 21)

First, a metal layer and a transparent conductive oxide layer are sequentially formed on the first surface of the circuit board 11 by a sputtering method, for example, and patterning is then performed on the metal layer and the transparent conductive oxide layer, using a photolithography technique and an etching technique, for example. As a result, the plurality of first electrodes 21 is formed on the first surface of the circuit board 11.

### (Step of Forming the Insulating Layer 12)

Next, the insulating layer 12 is formed on the first surface of the circuit board 11 so as to cover the plurality of first electrodes 21, by a chemical vapor deposition (CVD) method, for example. Next, the openings 12A are formed in portions of the insulating layer 12 located in the first surfaces of the respective first electrodes 21, by a photolithography technique and a dry etching technique, for example.

### (Step of Forming the OLED Layer 22)

Next, by a vapor deposition method, for example, a hole transport layer, a red light emitting layer, a light emitting separation layer, a blue light emitting layer, a green light emitting layer, an electron transport layer, and an electron injection layer are stacked in this order on the first surfaces of the plurality of first electrodes 21 and on the first surface of the insulating layer 12, to form the OLED layer 22.

### (Step of Forming the Second Electrode 23)

Next, the second electrode 23 is formed on the first surface of the OLED layer 22 by a vapor deposition method or a sputtering method, for example. As a result, the plurality of light emitting elements 20 is formed on the first surface of the circuit board 11.

### (Step of Forming the Si-Containing Layer 13)

Next, the Si-containing layer 13 is formed on the first surface of the second electrode 23 by a CVD method, for example.

### (Step of Forming the Metal Oxide Layer 14)

Next, the metal oxide layer 14 is formed on the first surface of the Si-containing layer 13 by atomic layer deposition (ALD), for example. Next, all or part of the portion of the metal oxide layer 14 corresponding to the seal region R2 is removed by a photolithography technique and a dry etching technique, for example. As a result, the closed-loop exposed portion 13A surrounding the display region R1 is formed.

### (Step of Forming the Color Filter 15)

Next, a coloring composition for forming green filter portions is applied onto the first surface of the metal oxide layer 14, and, after pattern exposure by irradiation with ultraviolet rays via a photomask, development is performed to form the green filter portions 15G. Next, a coloring composition for forming red filter portions is applied onto the first surface of the metal oxide layer 14, and, after pattern exposure by irradiation with ultraviolet rays via a photomask, development is performed to form the red filter portions 15R. Next, a coloring composition for forming blue filter portions is applied onto the first surface of the metal oxide layer 14, and, after pattern exposure by irradiation with ultraviolet rays via a photomask, development is performed to form the blue filter portions 15B. As a result, the color filter 15 is formed on the first surface of the metal oxide layer 14.

### (Sealing Step)

Next, a sealing agent is applied onto the exposed portion 13A in a closed loop shape surrounding the display region R1 to form a frame, and a filling resin is then applied to the inside of the frame. Next, the counter substrate 19 is placed on the filling resin and the sealing agent. Next, the sealing agent and the filling resin are cured by at least one of a heat treatment or an ultraviolet irradiation treatment, for example. As a result, the counter substrate 19 and the exposed portion 13A are bonded to each other by the seal portion 18, and the filling resin layer 16 is formed inside the seal portion 18. As described above, the display device 10 illustrated in FIGS. 2 and 3 is obtained. Note that the method for curing the filling resin and the sealing agent is not limited to a heat treatment and an ultraviolet irradiation treatment, but may be a curing method that is neither a heat treatment nor an ultraviolet irradiation treatment.

### [Mechanism of Adhesiveness Improvement]

In a case where the seal portion 18 contains a silane coupling agent, it is presumed that the adhesiveness of the seal portion 18 is increased by the mechanism described below.

In the sealing step, a sealing agent 18A containing a silane coupling agent is applied onto the exposed portion 13A, as illustrated in FIG. 5A. After the application, when the sealing agent 18A is subjected to a heat treatment, or the sealing agent 18A is irradiated with ultraviolet rays, the reaction between the silane coupling agent contained in the sealing agent 18A and the material (silicon nitride (SiNₓ), for example) contained in the Si-containing layer 13 is accelerated, and Si—O bonds are formed at the joint interface between the Si-containing layer 13 and the sealing agent 18A, as illustrated in FIG. 5B. As a result, the adhesiveness of the joint interface between the Si-containing layer 13 and the sealing agent 18A is increased.

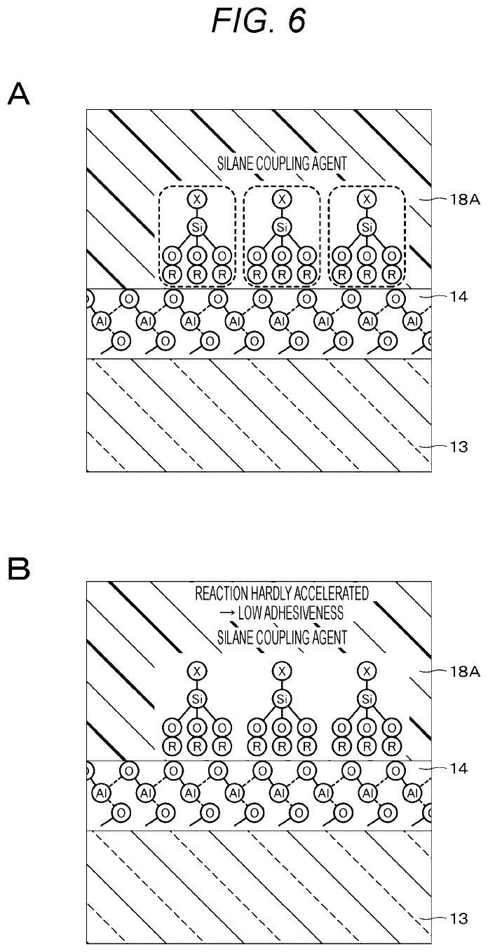

On the other hand, in a case where the sealing agent 18A containing a silane coupling agent is applied onto the metal oxide layer 14, as illustrated in FIG. 6A, even if the sealing agent 18A is subjected to a heat treatment or the sealing agent 18A is irradiated with ultraviolet rays, the reaction between the silane coupling agent contained in the sealing agent 18A and the material (aluminum oxide (AlOₓ), for example) contained in the metal oxide layer 14 is less likely to be accelerated, as illustrated in FIG. 6B. For this reason, Si—O bonds are hardly formed at the joint interface between the metal oxide layer 14 and the sealing agent 18A, and the adhesiveness at the joint interface between the metal oxide layer 14 and the sealing agent 18A becomes lower.

### [Functions and Effects]

In the display device 10 according to the first embodiment, the Si-containing layer 13 has the exposed portion 13A exposed without being covered with the metal oxide layer 14 in the seal region R2, and the seal portion 18 is provided on the exposed portion 13A, and is in direct contact with the exposed portion 13A. As a result, the adhesiveness between the seal portion 18 and the underlayer can be increased. Accordingly, entry of moisture from the outside of the display device 10 can be prevented. Thus, the reliability of the display device 10 can be increased.

Further, as entry of moisture from the outside of the display device 10 can be prevented, the reliability of the display device 10 can be maintained even in a case where the particle 1 adheres thereto during the manufacturing process.

### [Modifications]

### (Modification 1)

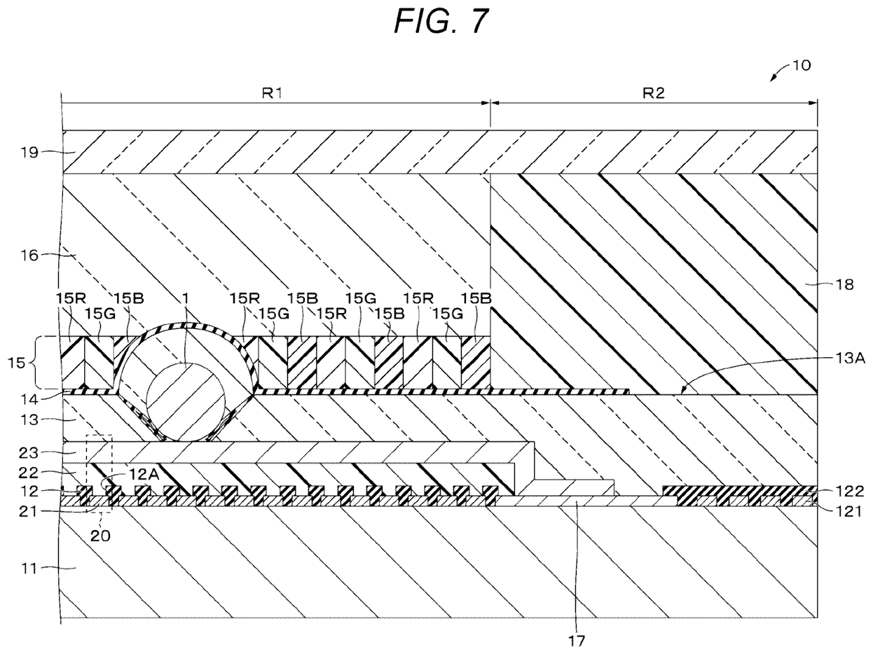

Although an example in which substantially the entire seal region R2 is the exposed portion 13A has been described in the first embodiment, at least part of the seal region R2 may be the exposed portion 13A. That is, as illustrated in FIG. 3, the width of the seal region R2 may be the same as the width of the exposed portion 13A, or, as illustrated in FIG. 7, the width of the seal region R2 may be greater than the width of the exposed portion 13A. Alternatively, the width of the seal region R2 may be smaller than the width of the exposed portion 13A. Note that the width of the seal region R2 is equal to the width of the seal portion 18.

In a case where the width of the seal region R2 is greater than the width of the exposed portion 13A, the inner periphery of the exposed portion 13A may be located on the outer side of the inner periphery of the seal region R2. In this case, the seal portion 18 may be provided on both the exposed portion 13A and the peripheral edge portion of the first surface of the metal oxide layer 14.

### (Modification 2)

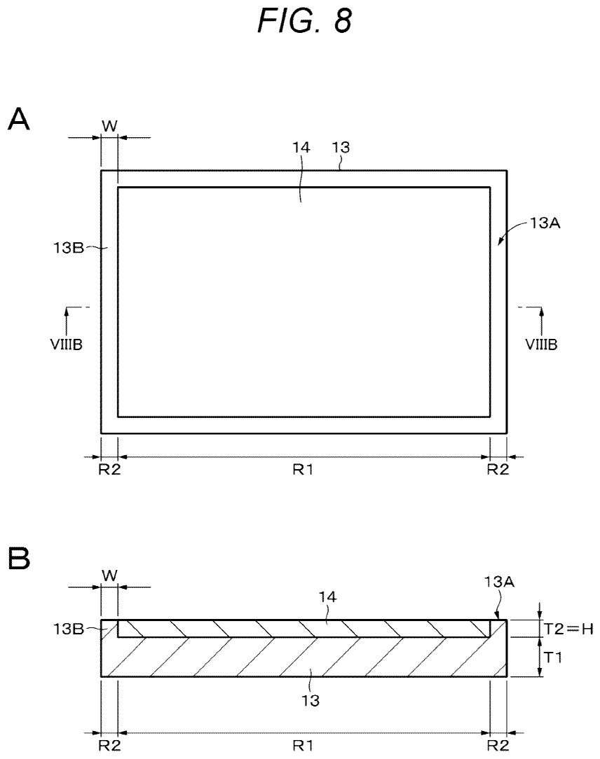

As illustrated in FIGS. 8A and 8B, the Si-containing layer 13 may have a protruding portion 13B on the first surface. The protruding portion 13B protrudes toward the seal portion 18. The top portion of the protruding portion 13B forms the exposed portion 13A that is not covered with the metal oxide layer 14 and is exposed, and is in direct contact with the seal portion 18. The shape of the top portion of the protruding portion 13B is not limited to any particular shape, but may be a planar shape, the shape of an inclined surface, the shape of a curved surface, or the like, for example. The protruding portion 13B is preferably in the form of a closed loop surrounding the display region R1 in a planar view.

The protruding portion 13B is provided in the seal region R2. The protruding portion 13B may be provided at a peripheral edge portion of the first surface of the Si-containing layer 13. The metal oxide layer 14 is provided inside the protruding portion 13B. The width of the seal region R2 may be the same as the width W of the protruding portion 13B, or the width of the seal region R2 may be greater than the width W of the protruding portion 13B. That is, the seal portion 18 may be provided only on the protruding portion 13B, or may be provided on both the protruding portion 13B and the peripheral edge portion of the first surface of the metal oxide layer 14. The height of the first surface of the metal oxide layer 14 and the height H of the protruding portion 13B may be the same, and the first surface of the metal oxide layer 14 and the top portion of the protruding portion 13B may be in the same plane.

The height H of the protruding portion 13B is preferably not smaller than 5 nm and not greater than 200 nm. The width W of the protruding portion 13B is preferably 5 mm or smaller, or more preferably, 2 mm or smaller, to make the frame of the display device 10 smaller. The protruding portion 13B may be formed with a material similar to that of the Si-containing layer 13.

### (Modification 3)

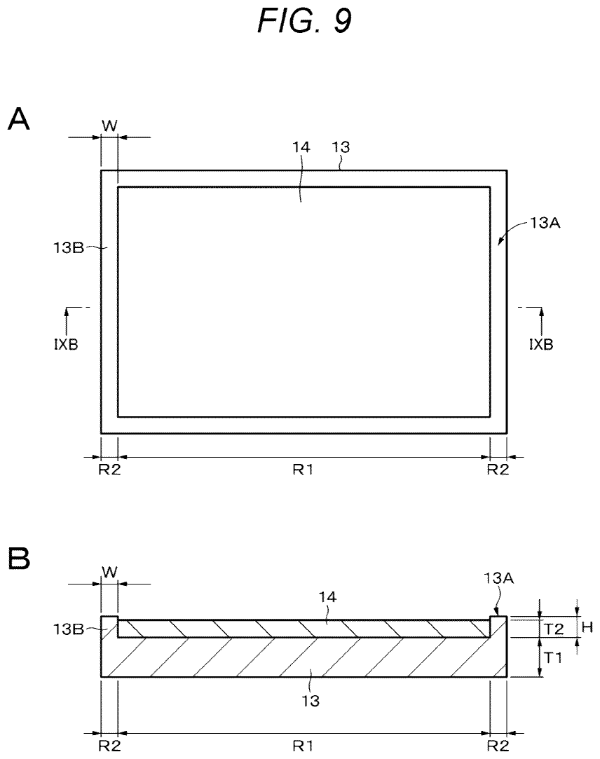

In Modification 2, an example in which the height of the first surface of the metal oxide layer 14 is the same as the height H of the protruding portion 13B has been described. However, as illustrated in FIGS. 9A and 9B, the height H of the protruding portion 13B may be greater than the height of the first surface of the metal oxide layer 14. Alternatively, the height H of the protruding portion 13B may be smaller than the height of the first surface of the metal oxide layer 14.

### (Modification 4)

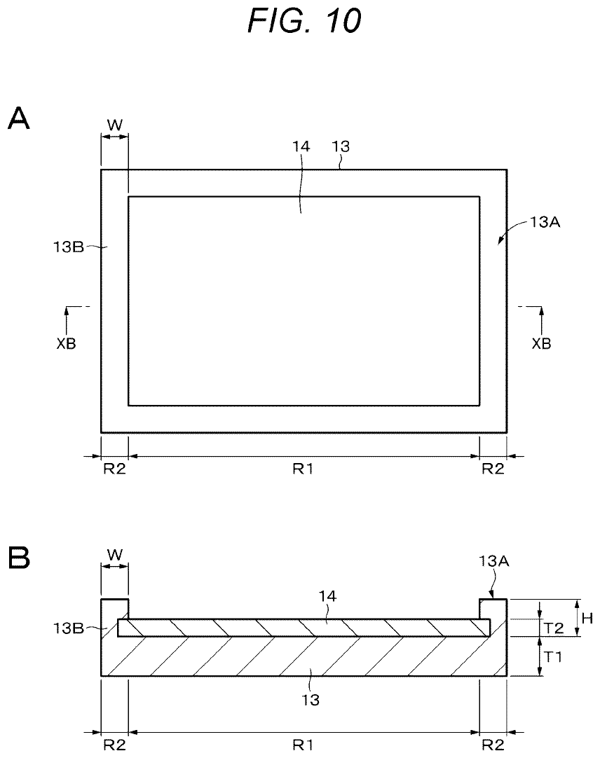

As illustrated in FIGS. 10A and 10B, the tip portion of the protruding portion 13B may protrude toward the center of the display region R1, and cover the peripheral portion of the first surface of the metal oxide layer 14. A cross-section of the protruding portion 13B may have an L shape.

### (Modification 5)

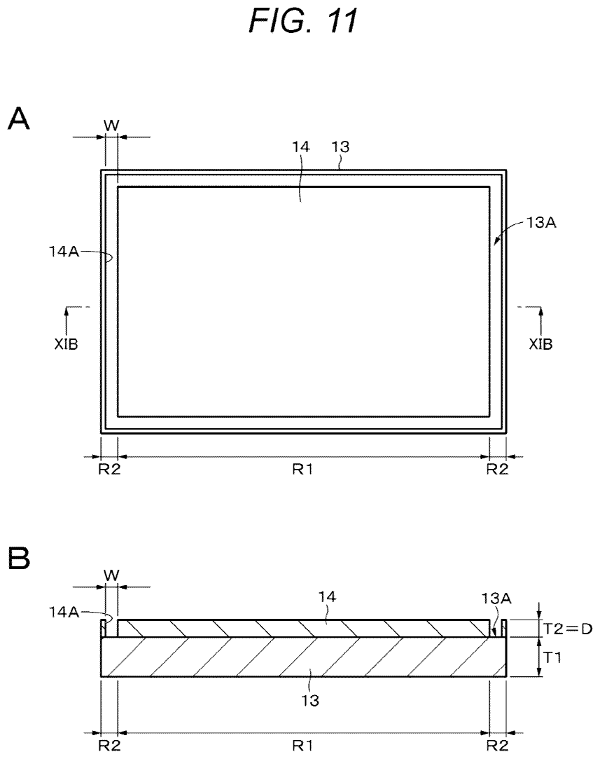

As illustrated in FIGS. 11A and 11B, the metal oxide layer 14 may have an opening 14A in the seal region R2 outside the display region R1. Part of the first surface of the Si-containing layer 13 may be exposed through the opening 14A, to form the exposed portion 13A. Part of the seal portion 18 fills the opening 14A, and the seal portion 18 is in direct contact with the exposed portion 13A via the opening 14A. The opening 14A preferably has the shape of closed loop surrounding the display region R1 in a planar view.

The opening 14A is provided in the seal region R2. The opening 14A may be provided along the peripheral edge of the metal oxide layer 14. The width of the seal region R2 may be the same as the width of the opening 14A, or the width of the seal region R2 may be greater than the width of the opening 14A. The depth D of the opening 14A is preferably not smaller than 5 nm and not greater than 200 nm. The width W of the opening 14A is preferably 5 mm or smaller, or more preferably, 2 mm or smaller, to make the frame of the display device 10 narrower.

### 3. Second Embodiment

### [Configuration of a Display Device 10A]

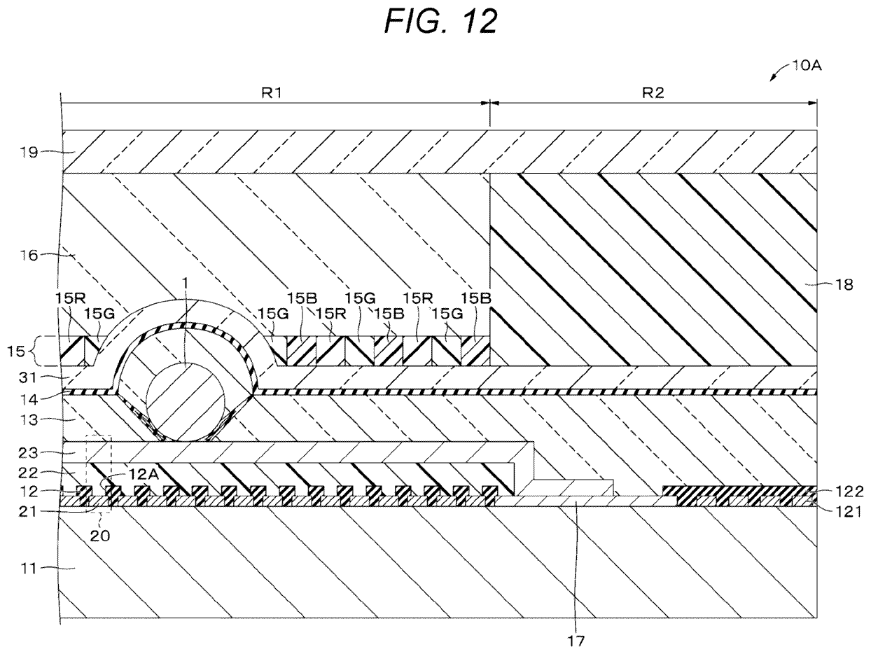

FIG. 12 is a cross-sectional view illustrating an example configuration of a display device 10A according to a second embodiment. The display device 10A differs from the display device 10 according to the first embodiment in that a Si-containing layer 31 is further provided on the first surface of the metal oxide layer 14, and the positions of the side surfaces of the Si-containing layer 13, the metal oxide layer 14, and the Si-containing layer 31 substantially coincide. The Si-containing layer 13 and the Si-containing layer 31 are an example of the first Si-containing layer and the second Si-containing layer, respectively.

The Si-containing layer 31 is a third protective layer that protects the plurality of light emitting elements 20. The Si-containing layer 31 has transparency to visible light. The Si-containing layer 31 is provided on the first surface of the metal oxide layer 14, and covers substantially the entire first surface of the metal oxide layer 14. The Si-containing layer 31 can prevent entry of moisture into the plurality of light emitting elements 20 from an external environment.

As the material of the Si-containing layer 31, a material similar to that of the Si-containing layer 13 can be taken as an example. The Si-containing layer 31 and the Si-containing layer 13 may be formed with the same material, or may be formed with different materials.

The seal portion 18 is in direct contact with the first surface of the Si-containing layer 31 in the seal region R2 outside the display region R1. The joint interface between the Si-containing layer 31 and the seal portion 18 preferably contains Si—O bonds. As the Si-containing layer 31 and the seal portion 18 are bonded to each other via the Si—O bonds, adhesiveness between the Si-containing layer 31 and the seal portion 18 can be increased.

### [Functions and Effects]

In the second embodiment, the Si-containing layer 31 is provided on the first surface of the metal oxide layer 14, and the seal portion 18 is in direct contact with the first surface of the Si-containing layer 31 in the seal region R2 outside the display region R1. As a result, the adhesiveness between the seal portion 18 and the underlayer can be increased. Accordingly, entry of moisture from the outside of the display device 10A can be prevented. Thus, the reliability of the display device 10A can be increased.

### [Modifications]

### (Modification 1)

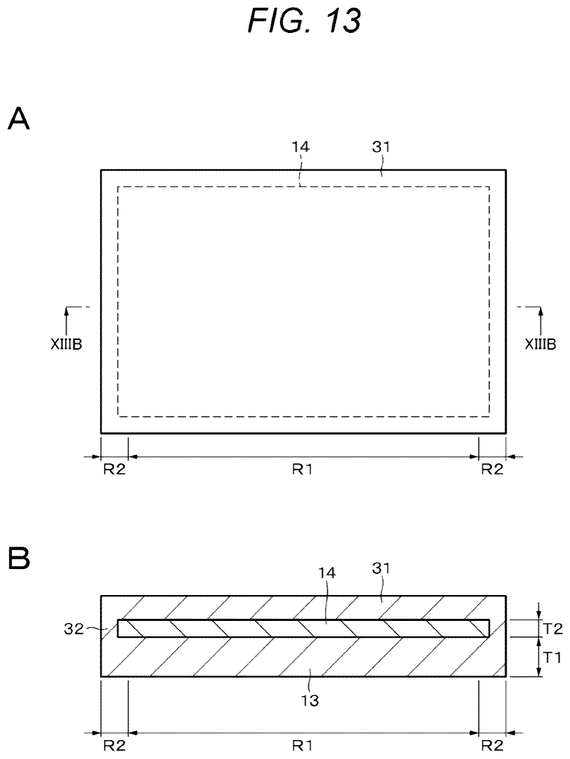

As illustrated in FIGS. 13A and 13B, a sidewall 32 covering the side surfaces of the metal oxide layer 14 may be provided. The sidewall 32 is provided in the seal region R2 outside the display region R1. The sidewall 32 may have the shape of a closed loop surrounding the side surfaces of the metal oxide layer 14 in a planar view. The peripheral edge portion of the first surface of the Si-containing layer 13 and the peripheral edge portion of the second surface of the Si-containing layer 31 may be connected by the sidewall 32. That is, the metal oxide layer 14 may be provided inside one protective layer. The sidewall 32 may be formed with a material similar to that of the Si-containing layer 13 and/or the Si-containing layer 31.

### (Modification 2)

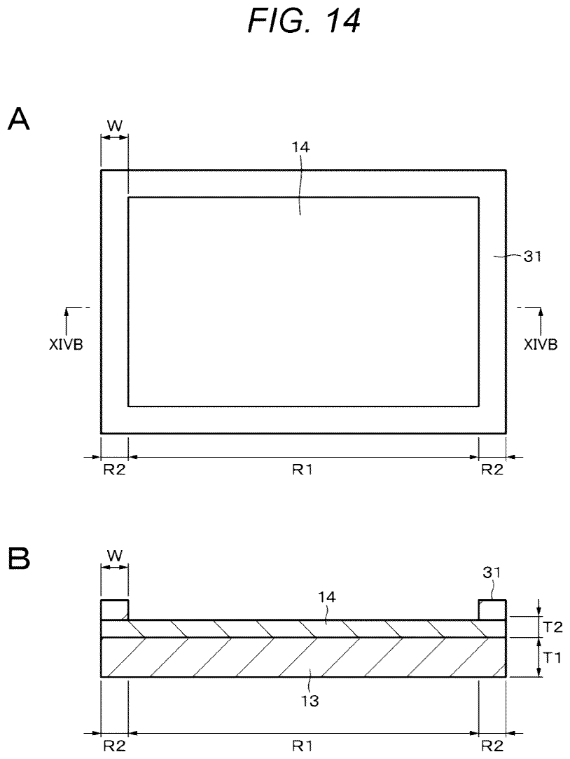

As illustrated in FIGS. 14A and 14B, the Si-containing layer 31 may be provided only in the seal region R2 outside the display region R1. At least part of the seal portion 18 is in contact with the first surface of the Si-containing layer 31. The width of the seal region R2 may be the same as the width W of the Si-containing layer 31, or the width of the seal region R2 may be greater than the width W of the Si-containing layer 31. That is, the seal portion 18 may be provided only on the first surface of the Si-containing layer 31, or may be provided on both the first surface of the Si-containing layer 31 and the first surface of the metal oxide layer 14. The Si-containing layer 31 preferably has the shape of a closed loop surrounding the display region R1 in a planar view. The width W of the Si-containing layer 31 is preferably 5 mm or smaller, or more preferably, 2 mm or smaller, to make the frame of the display device 10A narrower.

### 4. Modifications

Although the first and second embodiments of the present disclosure and modifications thereof have been specifically described above, the present disclosure is not limited to the above-described first and second embodiments and modifications thereof, and various modifications based on the technical idea of the present disclosure can be made.

For example, the configurations, methods, steps, shapes, materials, numerical values, and the like mentioned in the above-described first and second embodiments and modifications thereof are merely examples, and configurations, methods, steps, shapes, materials, numerical values, and the like different from these may be used as necessary.

For example, the configurations, methods, steps, shapes, materials, numerical values, and the like of the above-described first and second embodiments and modifications thereof can be combined with each other without departing from the gist of the present disclosure.

For example, each of the materials taken as examples in the above-described first and second embodiments and modifications thereof can be used independently, or two or more of the materials may be combined, unless otherwise specified.

In the first embodiment, the second embodiment, and the modifications thereof, examples in which the light emitting elements are OLED elements have been described. However, the light emitting elements are not limited to these examples, and may be light emitting diodes, semiconductor lasers, or the like. Further, two or more kinds of OLED elements, light emitting diodes, semiconductor lasers, and the like may be combined.

In the first embodiment, the second embodiment, and the modifications thereof, examples in which the light emitting device is a display device have been described. However, the light emitting device is not necessarily a display device, and may be a lighting device or the like. The lighting device may include one light emitting element, or may include a plurality of light emitting elements.

In the first embodiment, the second embodiment, and the modifications thereof, examples in which the sealing device is a light emitting device (specifically, a display device) have been described. However, the sealing device is not necessarily a light emitting device, and may be a light receiving device or the like including one light receiving element or a plurality of light receiving elements.

The light receiving element may be a photodiode, a solar cell, or a CMOS image sensor, for example.

In the first embodiment, the second embodiment, and the modifications thereof, examples in which the seal portion has the shape of a closed loop in a planar view have been described. However, the seal portion may be divided at one location or at two or more locations.

Further, the present disclosure may also adopt the following configurations.

(1)

A light emitting device including:
a plurality of light emitting elements provided in a display region;
a Si-containing layer that covers the plurality of light emitting elements;
a metal oxide layer provided on the Si-containing layer; and
a seal portion that is provided outside the display region and contains an organic resin, in which
the Si-containing layer has an exposed portion that is not covered with the metal oxide layer and is exposed outside the display region, and the seal portion is in contact with the exposed portion.
   (2)

The light emitting device according to (1), in which
the seal portion is provided on the exposed portion, or on both the exposed portion and the metal oxide layer.
   (3)

The light emitting device according to (1) or (2), in which
the exposed portion is formed by causing a peripheral edge of the metal oxide layer to retreat with respect to a peripheral edge of the Si-containing layer.
   (4)

The light emitting device according to (1) or (2), in which
the Si-containing layer has a protruding portion outside the display region, the protruding portion protruding toward the seal portion, and
the protruding portion forms the exposed portion.
   (5)

The light emitting device according to (4), in which
a tip portion of the protruding portion covers a peripheral edge portion of an upper surface of the metal oxide layer.
   (6)

The light emitting device according to (1) or (2), in which
the metal oxide layer has an opening outside the display region, and
the exposed portion is formed by exposing the Si-containing layer through the opening.
   (7)

The light emitting device according to any one of (1) to (6), in which
a thickness of the Si-containing layer is not greater than 10 μm, and
a thickness of the metal oxide layer is not smaller than 5 nm and not greater than 200 nm.
   (8)

The light emitting device according to any one of (1) to (7), in which
a width of the exposed portion is not greater than 5 mm.
   (9)

The light emitting device according to any one of (1) to (8), in which
the Si-containing layer contains silicon (Si) and nitrogen (N), or contains silicon (Si), oxygen (O), and nitrogen (N).
   (10)

The light emitting device according to any one of (1) to (9), in which
the metal oxide layer includes a monolayer.
   (11)

The light emitting device according to any one of (1) to (10), in which
an interface between the Si-containing layer and the seal portion includes a Si—O bond.
   (12)

The light emitting device according to any one of (1) to (11), in which
the seal portion contains a silane coupling agent.
   (13)

The light emitting device according to any one of (1) to (12), in which
the seal portion contains at least one of an ultraviolet curable resin or a thermosetting resin.
   (14)

The light emitting device according to any one of (1) to (13), in which
the seal portion has a shape of a closed loop in a planar view.
   (15)

A light emitting device including:
a plurality of light emitting elements provided in a display region;
a first Si-containing layer that covers the plurality of light emitting elements;
a metal oxide layer provided on the first Si-containing layer;
a second Si-containing layer provided on the metal oxide layer; and
a seal portion that is provided outside the display region and contains an organic resin, in which
the seal portion is in contact with the second Si-containing layer outside the display region.
   (16)

The light emitting device according to (15), in which
the second Si-containing layer has a shape of a closed loop in a planar view.
   (17)

The light emitting device according to (15), further including
a sidewall portion that covers a side surface of the metal oxide layer.
   (18)

An electronic apparatus including the light emitting device according to any one of (1) to (17).

(19)

A sealing device including:
a plurality of elements provided in an element formation region;
a Si-containing layer that covers the plurality of elements;
a metal oxide layer provided on the Si-containing layer; and
a seal portion that is provided outside the element formation region and contains an organic resin, in which
the Si-containing layer has an exposed portion that is not covered with the metal oxide layer and is exposed outside the element formation region, and the seal portion is in contact with the exposed portion.
   (20)

A sealing device including:
a plurality of elements provided in an element formation region;
a first Si-containing layer that covers the plurality of elements;
a metal oxide layer provided on the first Si-containing layer;
a second Si-containing layer provided on the metal oxide layer; and
a seal portion that is provided outside the element formation region and contains an organic resin, in which
the seal portion is in contact with the second Si-containing layer outside the element formation region.

### 5. Example Applications

### Electronic Apparatus

The display devices 10 and 10A (hereinafter referred to as the “display device 10 and the like”) according to the above-described embodiments and modifications thereof may be provided in various electronic apparatuses. The display device 10 and the like are suitable especially for an electronic viewfinder of a video camera or a single-lens reflex camera, a head-mounted display, or the like that requires high resolution and is used near the eyes in an enlarged manner.

### (Specific Example 1)

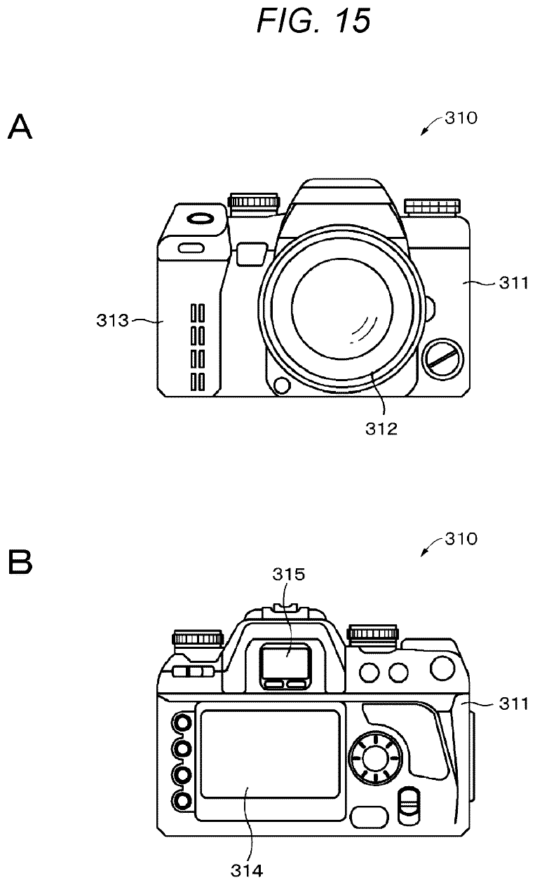

FIGS. 15A and 15B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip portion 313 to be held by the photographer on the front left side.

A monitor 314 is provided at a position shifted to the left from the center of the rear surface of the camera main body 311. An electronic viewfinder (eyepiece window) 315 is provided above the monitor 314. By looking through the electronic viewfinder 315, the photographer can visually recognize an optical image of the subject guided from the imaging lens unit 312, and determine a picture composition. The electronic viewfinder 315 includes any one of the display device 10 and the like described above.

### (Specific Example 2)

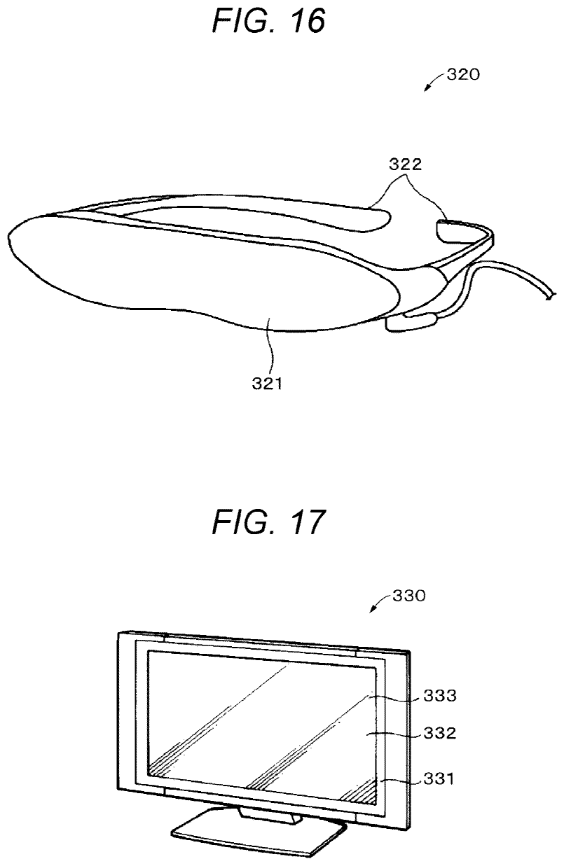

FIG. 16 illustrates an example of an external appearance of a head-mounted display 320. The head-mounted display 320 includes ear hooking portions 322 for the user to wear the head-mounted display 320 on the head, on both sides of a display unit 321 in the shape of eyeglasses, for example. The display unit 321 includes any one of the above-described display device 10 and the like.

### (Specific Example 3)

FIG. 17 illustrates an example of an external appearance of a television apparatus 330. The television apparatus 330 includes a video display screen unit 331 including a front panel 332 and a filter glass 333, and the video display screen unit 331 includes any one of the display device 10 and the like described above, for example.

### (Specific Example 4)

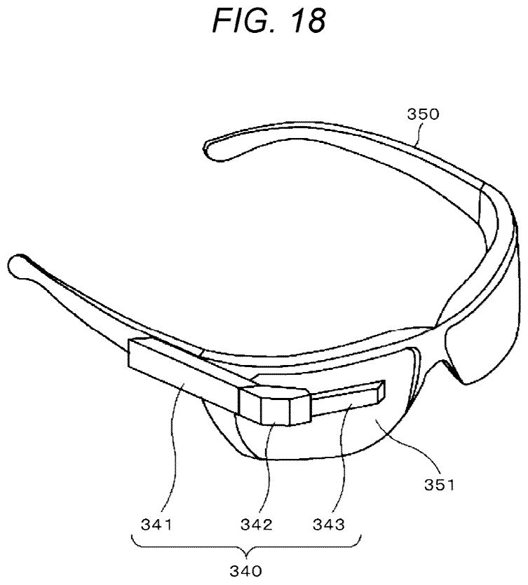

FIG. 18 illustrates an example of an appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be mounted directly on the head of the human body.

The main body 341 includes a control board for controlling operations of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 includes a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes one of the above display device 10 and the like.

### (Specific Example 5)

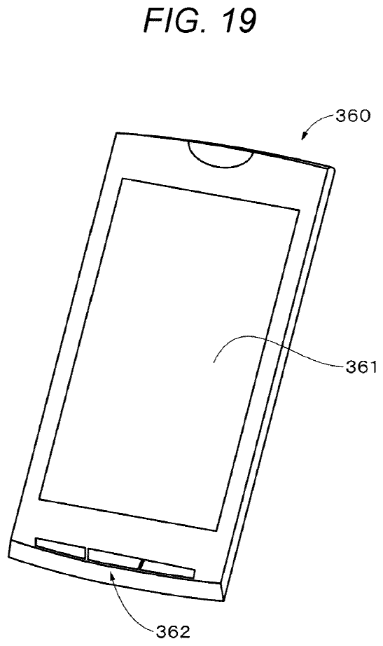

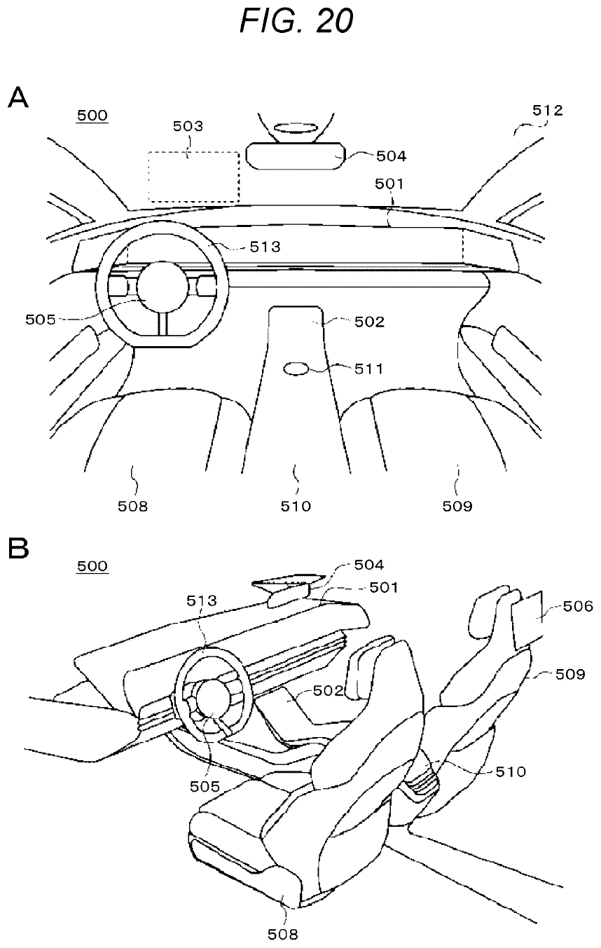

FIG. 19 illustrates an example of an external appearance of a smartphone 360. The smartphone 360 includes a display unit 361 that displays various kinds of information, an operation unit 362 formed with buttons for receiving operation inputs from the user, and the like. The display unit 361 includes any one of the above display device 10 and the like.

### (Specific Example 6)

The above display device 10 and the like may be provided in various displays provided in vehicles.

FIGS. 20A and 20B are views illustrating an example of an internal configuration of a vehicle 500 provided with various displays. Specifically, FIG. 20A is a view illustrating an example of an internal state of the vehicle 500 as viewed from the rear to the front of the vehicle 500, and FIG. 20B is a view illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes any one of the above display device 10 and the like. For example, all of these displays may include one of the above display device 10 and the like.

The center display 501 is disposed on the dashboard at a location facing a driver's seat 508 and a passenger seat 509. FIGS. 20A and 20B illustrate an example of the center display 501 having a horizontally elongated shape extending from the side of the driver's seat 508 to the side of the passenger seat 509, but the screen size and the placement location of the center display 501 are selected as appropriate. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, or the like. The center display 501 can be used to display at least one piece of information including safety-related information, operation-related information, lifelogs, health-related information, authentication/identification-related information, and entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information detects a gesture related to an operation by the occupant by using the sensor. Gestures to be sensed may include an operation of various kinds of equipment in the vehicle 500. For example, operations of air conditioning equipment, a navigation device, an audiovisual (AV) device, a lighting device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged by using an image sensor, and the health condition of the occupant may be estimated from the imaged facial expression. Moreover, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with a sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of information including the safety-related information, the operation-related information, the lifelogs, the health-related information, the authentication/identification-related information, and the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of information including the safety-related information, the operation-related information, the lifelogs, the health-related information, the authentication/identification-related information, and the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back surface side of the driver's seat 508 or the passenger seat 509, and is for an occupant in the rear seat to enjoy viewing/listening. The rear entertainment display 506 can be used to display at least one piece of information including the safety-related information, the operation-related information, the lifelogs, the health-related information, the authentication/identification-related information, and the entertainment-related information, for example. In particular, as the rear entertainment display 506 is located in front of an occupant in the rear seat, information related to the occupant in the rear seat is displayed. For example, information regarding operations of the AV device or the air conditioning equipment may be displayed, or a result of measurement of the body temperature or the like of an occupant in the rear seat with a temperature sensor may be displayed.

A sensor may be disposed on the back surface side of the display device 10 or the like in an overlapping manner, so that the distance to an object present in the surroundings can be measured. Optical distance measurement methods are roughly classified into a passive type and an active type. By a method of the passive type, distance measurement is performed by receiving light from an object, without projecting light from a sensor onto the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the above display device 10 and the like can be used in distance measurement by any of these methods. With a sensor disposed on the back surface side of the above display device 10 or the like in an overlapping manner, distance measurement of the passive type or the active type described above can be performed.

### REFERENCE SIGNS LIST

10, 10A Display device
11 Circuit board
12 Insulating layer
12A Opening
13, 31 Si-containing layer
13A Exposed portion
14 Metal oxide layer
15 Color filter
15R Red filter portion
15G Green filter portion
15B Blue filter portion
16 Filling resin layer
17 Contact portion
18 Seal portion
19 Counter substrate
20 Light emitting element
21 First electrode
22 OLED layer
23 Second electrode
R1 Display region
R2 Seal region
310 Digital still camera
320 Head-mounted display
330 Television apparatus
340 See-through head-mounted display
360 Smartphone
500 Vehicle

1. A light emitting device comprising:
a plurality of light emitting elements provided in a display region;
a Si-containing layer that covers the plurality of light emitting elements;
a metal oxide layer provided on the Si-containing layer; and
a seal portion that is provided outside the display region and contains an organic resin, wherein
the Si-containing layer has an exposed portion that is not covered with the metal oxide layer and is exposed outside the display region, and the seal portion is in contact with the exposed portion.

2. The light emitting device according to claim 1, wherein
the seal portion is provided on the exposed portion, or on both the exposed portion and the metal oxide layer.

3. The light emitting device according to claim 1, wherein
the exposed portion is formed by causing a peripheral edge of the metal oxide layer to retreat with respect to a peripheral edge of the Si-containing layer.

4. The light emitting device according to claim 1, wherein
the Si-containing layer has a protruding portion outside the display region, the protruding portion protruding toward the seal portion, and
the protruding portion forms the exposed portion.

5. The light emitting device according to claim 4, wherein
a tip portion of the protruding portion covers a peripheral edge portion of an upper surface of the metal oxide layer.

6. The light emitting device according to claim 1, wherein
the metal oxide layer has an opening outside the display region, and
the exposed portion is formed by exposing the Si-containing layer through the opening.

7. The light emitting device according to claim 1, wherein
a thickness of the Si-containing layer is not greater than 10 μm, and
a thickness of the metal oxide layer is not smaller than 5 nm and not greater than 200 nm.

8. The light emitting device according to claim 1, wherein
a width of the exposed portion is not greater than 5 mm.

9. The light emitting device according to claim 1, wherein
the Si-containing layer contains silicon (Si) and nitrogen (N), or contains silicon (Si), oxygen (O), and nitrogen (N).

10. The light emitting device according to claim 1, wherein
the metal oxide layer includes a monolayer.

11. The light emitting device according to claim 1, wherein
an interface between the Si-containing layer and the seal portion includes a Si—O bond.

12. The light emitting device according to claim 1, wherein
the seal portion contains a silane coupling agent.

13. The light emitting device according to claim 1, wherein
the seal portion contains at least one of an ultraviolet curable resin or a thermosetting resin.

14. The light emitting device according to claim 1, wherein
the seal portion has a shape of a closed loop in a planar view.

15. A light emitting device comprising:
a plurality of light emitting elements provided in a display region;
a first Si-containing layer that covers the plurality of light emitting elements;
a metal oxide layer provided on the first Si-containing layer;
a second Si-containing layer provided on the metal oxide layer; and
a seal portion that is provided outside the display region and contains an organic resin, wherein
the seal portion is in contact with the second Si-containing layer outside the display region.

16. The light emitting device according to claim 15, wherein
the second Si-containing layer has a shape of a closed loop in a planar view.

17. The light emitting device according to claim 15, further comprising
a sidewall portion that covers a side surface of the metal oxide layer.

18. An electronic apparatus comprising the light emitting device according to claim 1.

19. A sealing device comprising:
a plurality of elements provided in an element formation region;
a Si-containing layer that covers the plurality of elements;
a metal oxide layer provided on the Si-containing layer; and
a seal portion that is provided outside the element formation region and contains an organic resin, wherein
the Si-containing layer has an exposed portion that is not covered with the metal oxide layer and is exposed outside the element formation region, and the seal portion is in contact with the exposed portion.

20. A sealing device comprising:
a plurality of elements provided in an element formation region;
a first Si-containing layer that covers the plurality of elements;
a metal oxide layer provided on the first Si-containing layer;
a second Si-containing layer provided on the metal oxide layer; and
a seal portion that is provided outside the element formation region and contains an organic resin, wherein
the seal portion is in contact with the second Si-containing layer outside the element formation region.
